(19) United States
(12) Patent Application Publication
(10) Pub. No.: US 2008/0070414 A1
(43) Pub. Date: Mar. 20, 2008

(54) METHOD FOR DESIGNING MASK AND METHOD FOR MANUFACTURING SEMICONDUCTOR DEVICE EMPLOYING THEREOF

(75) Inventor: Hitoshi SHIRAISHI, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/856,746

(22) Filed: Sep. 18, 2007

(30) Foreign Application Priority Data
Sep. 19, 2006 (JP) 2006-252714

(51) Int. Cl. H01L 21/311; G06F 17/50

(52) U.S. Cl. 438/702; 716/19; 257/E21.249

(57) ABSTRACT

A bias correction level can be defined with an improved efficiency when a transfer pattern of a hole is formed, so that the hole can be stably formed as originally designed. When a hole pattern is formed over a substrate, correction reference holes 103 existing in a region 113, which is capable of affecting a formation of a correction target hole 101, is extracted, and a bias correction level employed in the formation of the correction target hole 101 is defined, in accordance with a two-dimensional arrangement of the extracted correction reference holes 103.

This application is based on Japanese patent application No. 2006-252714, the content of which is incorporated hereinto by reference.

### BACKGROUND

1. Technical Field

The present invention relates to a method for designing a mask and a mask design system in an optical exposure process and/or an electron beam exposure process, and in particular relates to a technology for forming a hole-pattern in a process for manufacturing a semiconductor device.

2. Related Art

In optical lithography, a portion of a photo resist layer formed on a substrate is irradiated with a light, and then a developing process is performed to form desired pattern in the photo resist layer. The optical exposure process ordinarily employs a procedure, in which a desired pattern is formed on a photo mask, and then the resist layer on the substrate is irradiated with the light using projection exposure system. The feature size in the resist layer is ordinarily reduced to 25% (or 20%) of its original feature size on the mask by the projection exposure system. Electron beam (EB) exposure processes typically include a method by employing an EB mask and a method by irradiating an electron beam only on desired position in the resist layer without employing an EB mask.

In the era of micron order design rules, it was considered that a design pattern (for example, pattern previously formed on a photo mask) and a pattern formed on the photo resist were substantially the same in such an exposure process.

However, in recent lithography for semiconductor integrated circuit, a progressed downscaling of device patterns causes a problem, in which a final dimension of a finished pattern actually formed thereon is not precisely coincident with the desired design dimension, and thus a difference created between the design dimension and the product dimension cannot be ignored.

It is considered that the main factor for such problem is that a geometry of a pattern formed in the resist layer depends not only on the geometry of the corresponding pattern on the photomask but additionally on an existence of surrounding pattern or an average level of a local irradiation, and such factor is called “proximity effect”.

An approach for solving such problem of formation failure is, for example, that a patterned mask having different dimension or shape from the design pattern is formed according to a level of a proximity effect to improve the pattern accuracy. This is called an optical proximity correction (OPC) technology.

The OPC process is, as described above, a technology for providing a correction against a layout-dependent deformation of a pattern generated in the micro-fabrication process by modifying a mask pattern, and is performed as a portion of a mask data processing. Thus, data presented through a mask data processing by the OPC processing is subjected under a program manipulation, so that data is converted to a pattern on a reticle, thereby forming the reticle.

Here, correction methods called the OPC technologies typically include a rule-base OPC, which is a correction method specialized in correcting an influence of the proximal pattern among influences of proximity effect, and is performed by obtaining a bias level (correction level) for adding to (or subtracting from) the design pattern according to a distance from a proximal pattern and then correcting the pattern on the basis of the bias level. The rule-base OPC is advantageous since the correction process is simple, and the program manipulation after the OPC process is achieved with a relatively shorter processing time, and therefore the rule-base OPC is a most frequently employed method in the OPC technologies.

A conventional technology for the rule-base OPC is specifically described in Japanese Patent Laid-Open No. 2005-316,134. Japanese Patent Laid-Open No. 2005-316,134 describes a method for performing a definition of a bias level for a line pattern to be corrected in accordance with a peripheral influence.

As described above, Japanese Patent Laid-Open No. 2005-316134 discloses that an influence of the line pattern in the periphery of the line pattern is corrected with a bias, according to a width and/or an interval of the pattern.

However, in cases of hole patterns such as contact holes 217 or via holes 223 as will be discussed later in reference to FIG. 7, an influence by a peripheral hole pattern is generally larger, as compared with line patterns as set forth in Japanese Patent Laid-Open No. 2005-316134. In addition, while Japanese Patent Laid-Open No. 2005-316,134 describes an evaluation for a correction of a line pattern in transverse direction perpendicular to an elongation direction of the pattern, such evaluation cannot be directly applied to a hole pattern, since a hole pattern includes patterns in longitudinal and diagonal directions, in addition to transverse direction.

Thus, a calculation for a hole pattern is difficult by the rule base OPC so that insufficient correction accuracy is achieved, since the hole pattern includes patterns in longitudinal and diagonal directions, in addition to patterns in transverse direction, even of the rule base OPC is applicable to the line pattern, and therefore there is no other choice than employing a model-base OPC. However, a computation process in a model-base OPC requires greater amount of time, leading to a larger load for mask-manufacturing process, thus the model-base OPC is not realistic for such application.

### SUMMARY

According to one aspect of the present invention, there is provided a method for designing a mask having a hole pattern, comprising: extracting peripheral holes existing in a region, which is capable of affecting a formation of a correction target hole; and defining a bias correction level employed in the formation of the correction target hole, in accordance with a two-dimensional arrangement of the peripheral hole extracted in the extracting peripheral holes.

According to another aspect of the present invention, there is provided a system for designing a mask, comprising: a data acquisition unit, which is capable of accepting data related to a hole pattern in a mask; and a calculating unit, which is capable of correcting a data related to the hole pattern acquired by the data acquisition unit to generate a corrected pattern, wherein the calculating unit is configured of extracting peripheral holes existing in a region, which is capable of affecting a formation of a correction target hole, and defining a bias correction level employed in the formation of the correction target hole, in accordance with a two-dimensional arrangement of the extracted peripheral hole.

According to the present invention, when a correction for holes is carried out by a rule base OPC, a pattern of holes within a certain region, which is capable of affecting a formation of a correction target hole, is extracted as a peripheral hole. Then, in accordance with a two-dimensional arrangement of the extracted peripheral hole, a bias correction level of the correction target hole is defined. This allows defining the bias correction level of the correction target hole with an improved efficiency. A bias correction level can be defined in accordance with, for example, influences in hole patterns existing in longitudinal direction and oblique direction, in addition to an influence in a hole pattern present in a transverse direction of a correction target hole or more specifically in addition to an influence in a hole pattern present in a specified axis-direction. In addition, since the transfer pattern of correction target hole in the mask can be corrected in accordance with an influence of peripheral holes, the correction target hole can be stably formed as originally designed.

According to the present invention, in said defining a bias correction level, said bias correction level is defined on the basis of center-to-center distances between said peripheral holes extracted in said extracting peripheral holes and said correction target hole, and on the basis of angles formed by the intersection of line connecting from centers of said peripheral holes to centers of said correction target hole and bias axis of said correction target hole.

Since the pattern of the correction target hole in the hole pattern utilizes the corrected mask as a transfer pattern in the above-described aspect of the present invention, a corrected hole pattern is formed on a film. Such hole pattern is formed in a film on the insulating film and a region corresponding to the hole pattern in the insulating film is selectively removed, so that the holes extending through the insulating film can be formed as originally designed. Thus, an improved production yield of semiconductor devices can be achieved.

As described above, according to the present invention, the bias correction level can be defined with an improved efficiency when the transfer pattern of the holes is formed, so that the hole can be stably formed as originally designed.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a diagram, showing a schematic configuration of an apparatus for designing a mask in an embodiment;

FIG. 2 is a plan view, useful in describing a method for designing a mask in an embodiment;

FIG. 3 is a plan view, useful in describing the method for designing a mask in the embodiment;

FIG. 4 is a plan view, useful in describing the method for designing a mask in the embodiment;

FIG. 5 is a plan view, useful in describing the method for designing a mask in the embodiment;

FIG. 6 is a flow chart, useful in describing a correction procedure in the embodiment.

FIG. 7 is a cross-sectional view, showing a configuration of a semiconductor device in the embodiment; and

FIGS. 8A and 8B are cross-sectional views, illustrating a process for manufacturing the semiconductor device of FIG. 7.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Preferable exemplary implementations according to the present invention will be described in reference to the annexed figures. In all figures, identical numeral is assigned to an element commonly appeared in the description of the present invention in reference to the figures, and the detailed description thereof will not be repeated. First of all, a method for designing a mask having a hole pattern will be described.

### First Embodiment

The present embodiment will present exemplary implementations of corrections for a certain hole included in a pattern having a plurality of holes such as contact holes, via holes and the like through a rule base OPC, in which a pattern of holes within a certain region, which is capable of affecting a formation of a correction target hole, is extracted, and then, a bias correction level is defined in consideration the influences thereof and more specifically the distance thereof to form a corrected pattern.

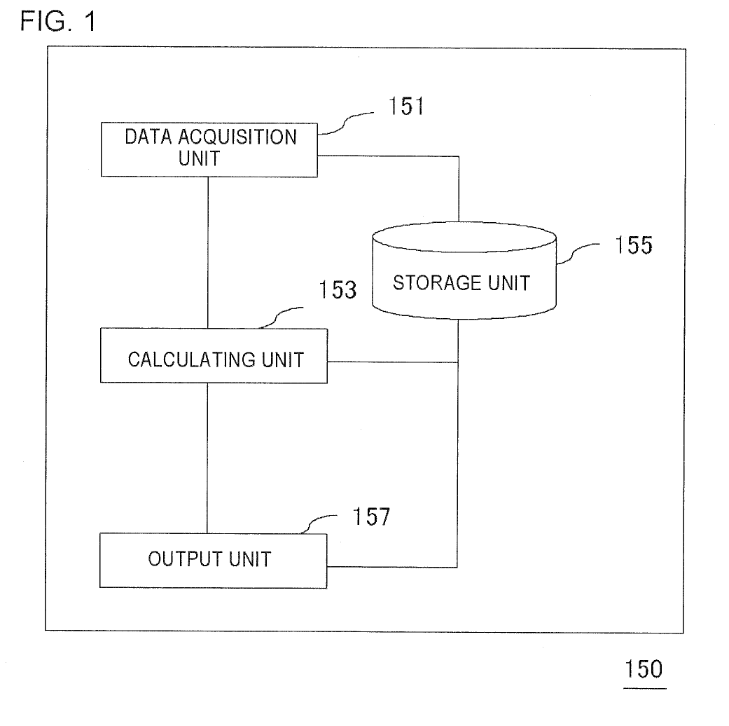

FIG. 1 is a block diagram, illustrating a configuration of a pattern-forming apparatus of the present embodiment. An apparatus 150 shown in FIG. 1 is an apparatus that is capable of calculating bias correction levels for correction target hole, and includes a data acquisition unit 151, a calculating unit 153, a storage unit 155 and an output unit 157. Such apparatus is ordinarily employed in a stage of designing a patterned mask.

The data acquisition unit 151 is capable of acquiring data related to a two-dimensional geometry of a transfer pattern of the mask. In addition, the output unit 157 is capable of outputting data of a corrected pattern, which is corrected in the calculating unit 153.

The storage unit 155 is a storage device that is capable of storing the information related to the two-dimensional geometry of the mask acquired in the data acquisition unit 151. Alternatively, the data acquisition unit 151 may acquire data of the mask previously stored in the storage unit 155. Typical devices utilized for the storage unit 155 include, storage devices such as, for example, a random access memory (RAM), a flash memory, a hard disk drive (HDD) and the like. In addition to above, the storage unit 155 may also store the correction bias level calculated by the calculating unit 153 as will be discussed later, or numeral values that are employed for such calculation. For example, the bias level as will be discussed later may be stored in association with a center-to-center distance of holes.

The calculating unit 153 is capable of calculating the bias correction levels for the correction target hole in the mask on the basis of a two-dimensional geometry of the mask accepted by the data acquisition unit 151 to create a corrected pattern. Typical devices utilized for the calculating unit 153 may include, for example, a central processing unit (CPU). The method for designing the hole pattern in the calculating unit 153 will be described as follows.

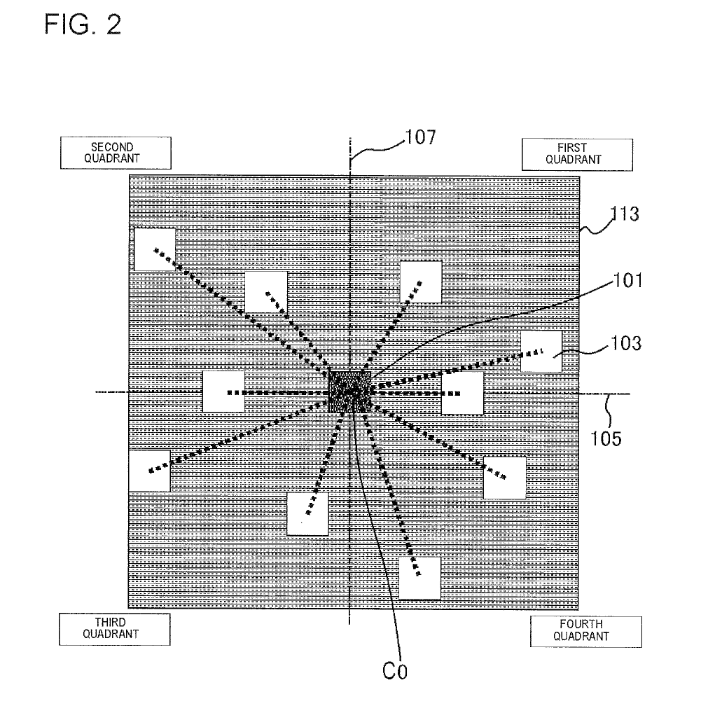

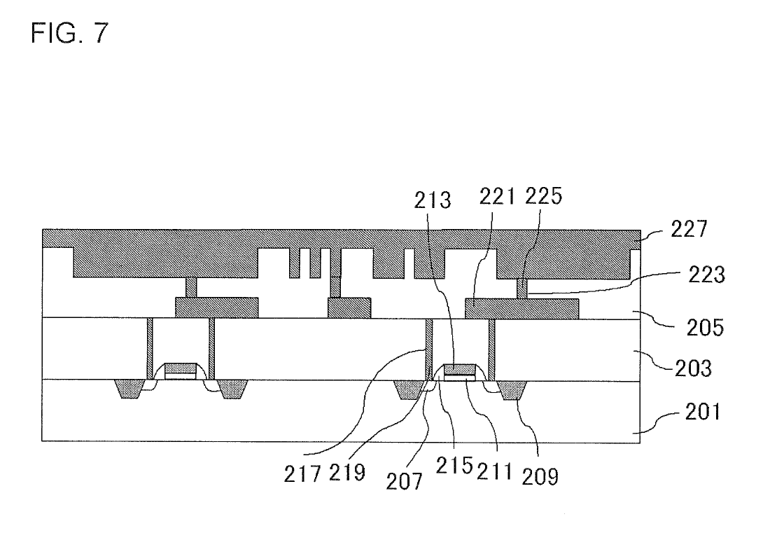

FIG. 2 is a diagram, useful in describing the method for forming the patterned mask including patterns of holes such as contact holes 217, via holes 223 shown in FIG. 7, More specifically, FIG. 2 is a plan view, illustrating a range for searching the holes to be referred in the correction process. Typical mask figure for forming holes is designed, for example, a square, a rectangle to which the vicinity of length and short vicinity are almost equal, or modified pattern thereof.

The method for designing the mask according to the present embodiment is a method for forming a pattern of holes formed over semiconductor substrate (wafer), which contains a main section including elements such as transistors, and comprises the following process operations.

step 21: extracting peripheral holes (correction reference holes 103) existing in a region 113, which is capable of affecting a formation of a correction target hole 101; and

step 22: defining a bias correction level employed in the formation of the correction target hole 101, a two-dimensional arrangement of the correction reference holes 103 extracted in the previous operation of extracting correction reference holes 103.

Alternatively, an operation (step 23) of designing a mask through a correction with the above-described correction level, and forming a pattern over the wafer by employing the mask may be further included.

In step 21, as shown in FIG. 2, searches for the correction reference hole 103 are carried out over all directions in a range (region 113) a predetermined peripheral range from the correction target hole 101. In addition to above, in FIG. 2, a case of employing the correction target hole 101 having a square pattern and the region 113 having a square geometry provided in concentric arrangement with the correction target hole 101 is exemplified. The following description exemplifies a case of employing the correction target hole having rectangular turn such as square and the like. The range for searching in this case is defined to be, for example, a range of 500 nm×500 nm square from the center of the correction target side.

In addition to above, the geometry of the region 113 is not limited to a square region, and, for example, may be a circular region of a predetermined radius having a center C0, which is identical with the center of the correction target hole 101.

The region 113, which is a range for searching the correction reference holes 103, is a range for affecting the correction target hole 101 with a proximity effect, and holes in location out of the above-described range for searching may be regarded as out of target, since the distance thereof from the correction target hole 101 is a distance that promotes no influence of the proximity effect.

In step 22 that is for defining the bias correction level, center-to-center distances between the correction target hole 101 and the correction reference holes 103 are measured for all of the detected correction reference holes 103 to obtain the distances between the centers of these holes.

Next, a method for calculating the correction level for the correction target side will be described. Such step 22 may be performed by, for example, the calculating unit 153, and may further include the following operations:

step 24: preliminarily acquiring a relationship between distances from the center of the correction target hole 101 to the centers of the correction reference holes 103 and the bias correction level;

step 25: calculating center-to-center distances between the correction reference holes 103 extracted in the extracting correction reference holes 103 and the correction target hole 101; and

step 26: defining the bias correction level for the correction target hole 101 from the center-to-center distance calculated in step 25, in reference to the relationship acquired in step 24.

When the correction target hole 101 is rectangular as in the present embodiment, the bias correction levels may be defined for the respective four sides of the rectangular geometry. In addition to above, correction directions in the respective sides are, for example, a direction perpendicular to the side.

Alternatively, in step 22 that involves defining the bias correction level, a bias correction level may be calculated for each of “n” correction reference holes 103 (n is a positive integer) extracted in step 21 that involves extracting the correction reference holes 103, such that the bias correction level for the correction target hole 101 is defined as a function of the “n” bias correction levels, or more specifically as a function of the grand total thereof. The exemplary implementations will be described in the above-described case.

Table 1 shows a relationship (bias table) between the center-to-center distance acquired in step 24 and the bias correction level (bias A). The bias table shown in table 1 discloses the relationship between a correction reference hole 103 among the plurality of the correction reference holes 103 and the correction target hole 101.

TABLE 1
BIAS TABLE

(UNIT: nm)

| | CENTER-TO-CENTER | | | | | | |
|---|---|---|---|---|---|---|---|
| | DISTANCE X | | | | | | |
| | x < 150 | 150 ≦ x < 200 | 200 ≦ x < 250 | 250 ≦ x < 300 | 300 ≦ x < 350 | 350 ≦ x < 400 | 400 ≦ x |
| Bias A | −4 | −6 | −3 | −2 | −1.5 | −0.5 | 0 |
| (REFERENCE VALUE) | | | | | | | |

In step 25, distances between the correction target hole 101 and the correction reference holes 103 are acquired for the respective “n” peripheral holes extracted in step 21 for extracting the correction reference hole 103.

In step 26, all of the correction levels for the correction reference hole 103 over the correction target hole 101 are calculated by employing the bias correction level that has been previously defined. In such case, the bias (bias A) corresponding to the center-to-center distance acquired in step 24 is determined for one of the correction reference holes 103. The bias is more specifically determined according to the bias included in table 1.

Here, it may be assumed that the sizes of the correction target hole 101 and the correction reference hole 103 are defined as, for example, 100 nm square without exception, and the bias levels are uniquely determined by a center-to-center distance between the correction reference hole 103 and the correction target hole 101.

In table 1, assuming that the center-to-center distance is x, the bias correction levels for 150 nm≦x<200 nm are defined to be relatively larger than the bias correction levels for other distances, since such distance provides the locations of the correction reference holes 103, where the proximity effect considerably acts over the correction target hole 101. As described above, the relationship between the center-to-center distance x and the strength of the proximity effect may be preliminarily acquired through experiments, and a bias correction level corresponding to a strength of proximity effect may be defined for each of the distances x.

In addition to above, the relationship of the bias correction level with the center-to-center distance shown in table 1 may be empirically acquired by, for example, a patterning of a pseudo wafer. Data of bias table shown in table 1 may be stored in the storage unit 155.

After n bias correction levels corresponding to each of n center-to-center distances are acquired, the final correction level for the correction target hole 101 is acquired as a function of n bias correction levels. More specifically, the final bias correction level is defined as a function of a grand total of n bias correction levels. The method for defining the final bias correction level may be suitably selected, and, for example, a sum total of n bias correction levels may be utilized for the bias correction level as it is, or a sum total of values, each of which is obtained by multiplying each of the n bias correction levels by a specified correction coefficient within a range of greater than 0 and smaller than 1, may be utilized for the bias correction level.

The method for defining the bias table shown in table 1 will be further described as follows. An estimation for the degree of the influence of the proximity effect over the correction target hole 101 for the center-to-center distance acquired in the above-described procedure, or more specifically an estimation for the correction level for adding to (or subtracting from) the design pattern according to a distance from a proximal pattern, is difficult by the calculation.

Further, while the most precise method may be a method for actually forming a pattern on a wafer by employing a mask designed with such center-to-center distances and hole sizes, and then measuring the dimension of the pattern to obtain the dimension for adding to (or subtracting from) the pattern, such method requires greater time for acquiring all center-to-center distances, and further the process stability should be also considered for acquiring the center-to-center distances. Thus, the method for actually forming the mask may not necessarily be an appropriate method.

In such case, in order to consider the influence of the proximity effect, a simulation model may be constructed that can reproduce precisely as much as possible the hole size formed on an actual wafer when process conditions for applying the resist on the actual wafer and for exposing and patterning the resist and optical conditions employed for an exposure equipment are retrieved in a simulation equipment, and the constructed simulation model may be employed to define a bias table (additional dimension for adding to the correction target hole for the center-to-center distance the adjacent holes) by determining the bias level as deviations between the adding (subtracting) dimensions calculated for the distances between the respective holes and the design hole size.

By correcting the patterned mask for forming holes in the above-mentioned procedure, the pattern of the correction target hole 101 can be adequately corrected, even if a correction reference hole 103 is present in the region 113 that affects the formation of the peripheral pattern of the correction target hole 101, so that the hole as originally designed can be stably formed.

Further, even if a number of correction reference holes 103 are present in the region 113, the present embodiment allows considering the influence of these correction reference holes 103. Further, since the bias correction level is adjusted according to the locations of the correction reference holes 103 relative to correction target hole 101, the bias correction level is advantageously reduced as compared with the conventional technology, thereby advantageously providing an improved correction accuracy.

In the following embodiments, descriptions will be made focusing on features that are different from first embodiment.

### Second Embodiment

In this embodiment, the bias correction level is calculated by multiplying the bias level determined from the distance between the holes by a correction factor as a function of an angle for a perpendicular line to the side of correction target hole.

In the present embodiment, the bias correction level is defined in step 22 for defining the bias correction level, on the basis of the center-to-center distance between a correction reference hole 103 extracted in step 21 for extracting the correction reference holes 103 and the correction target hole 101 and angles of a line connecting the center of the correction reference holes 103 and the center of the correction target hole 101 with the bias axis of the correction target hole 101.

In such case, step 22 includes, for example, the following steps.

step 27: defining a bias level of the correction target hole 101 on the basis of the center-to-center distance between the correction target hole 101 and the correction reference hole 103;

step 28: defining a correction factor for the bias level as a function of the above-described angle; and

step 29: utilizing a product obtained by multiplying the bias level by the correction factor as the bias correction level in a direction along the bias axis.

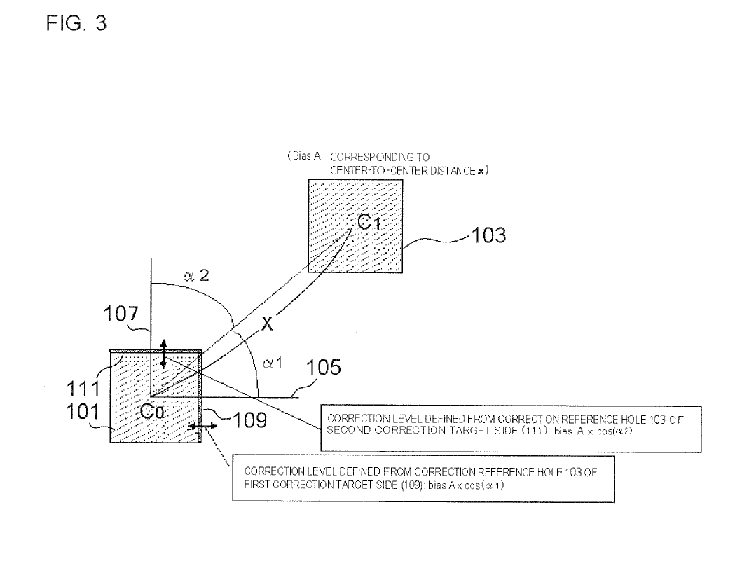

FIG. 3 is a diagram, useful in describing the method for defining the correction factor in step 28. In FIG. 3, a correction level is obtained by a correction reference hole 103 for correction target side. The correction level is obtained by the following formula.

correction level=bias A×cos α.

In the above-described formula for calculating the correction level, α is an angle between a center line connecting hole and a perpendicular line to a correction target side. The center line connecting hole, is a line connecting a center C0 of the correction target hole 101 with a center C1 of a correction reference hole 103, for example.

Further, in the present embodiment, step 22 includes defining bias correction levels in a direction of a first bias axis (first bias axis 105) and in a direction of a second bias axis (second bias axis 107) that is not in parallel with the first bias axis, respectively (step 30). Since the two-dimensional geometry of the correction target hole 101 is square in the present embodiment, the following descriptions will be made in reference to a diagram representing the first bias axis 105 that is perpendicular to the second bias axis 107 for easier comprehension. However, the first bias axis 105 may not be necessarily perpendicular to the second bias axis 107.

As shown in FIG. 3, a correction level in a direction along the first correction target side 109 is:

bias A×cos(α1).

Further, a correction level in a direction along the second correction target side 111 is given by:

bias A×cos(α2).

Step 22 includes more specifically the following steps.

step 24: preliminarily acquiring a relationship between a distance from a center of the correction target hole 101 to the center of the correction reference hole 103 and the bias level;

step 25: calculating center-to-center distance between the correction reference hole-103 extracted in the step 21 of extracting the correction reference holes 103 and the correction target hole 101;

step 31: acquiring a first correction factor on the first bias axis 105, which is a function of an angle between a line connecting a center of the correction reference hole 103 to a center of the correction target hole 101 and the first bias axis 105, and acquiring a second correction factor on the second bias axis 107, which is a function of an angle formed by an intersection of the aforementioned line and the second bias axis 107; and

step 32: defining a bias correction level in a direction of the first bias axis 105 for the first bias axis 105 as a function of a product of the bias level multiplied by the first correction factor, and defining a bias correction level in a direction of the second bias axis 107 for the second bias axis 107 as a function of a product of the bias level multiplied by the second correction factor.

In step 22, calculating a first value in which the bias level and the first correction factor are multiplied for each of “n” correction reference holes 103 (n is a positive integer) extracted in step 21, and a bias correction level in the direction of said first bias axis 105 is determined by a sum of the first value, Further, calculating a second value in which the bias level and the second correction factor are multiplied or each of “n” correction reference holes 103 (n is a positive integer) extracted in step 21, and a bias correction level in the direction of the second bias axis 107 is determined by a sum of the second value.

Thus, the final correction level for n correction reference holes 103 found in the first correction target side 109 is presented as, according to FIG. 2:

Σ(bias Ai×cos(α1i))

(where “i” is a positive integer from 1 to n).

Similarly, the final correction level for n correction reference holes 103 found in the second correction target side 111 is presented as:

Σ(bias Ai×cos(α2i))

(where “i” is a positive integer from 1 to n).

Further, in the present embodiment, the bias correction level for the correction target hole 101 in the first correction target side 109 may be determined by the following formula (I):

(sum of bias correction levels for correction reference holes 103 detected in the first and the fourth quadrants)+(sum of bias correction levels for correction reference holes 103 detected in the second and the third quadrants)×(correction factor a)(1)

(where 0<a<1).

Here, the correction factor a is a factor employed for the correction levels related to locations, which out of the visual range from the correction target hole 101 (the second and the third quadrants in FIG. 2), and defined to be smaller, as 0<a<1.

The location of out of the visual range is a location where the pattern of the correction target hole 101 is present between the correction target side having the correction target hole 101 and the correction reference hole 103. For example, the second and the third quadrants are in the location of out of the visual range for the first correction target side 109, and the first and the fourth quadrants are in the location of out of the visual range for the second correction target side 111.

The reason for multiplying the correction level of the correction reference hole 103 detected in the second and the third quadrants by the correction factor a (0<a<1) for the first correction target side 109 is as follows.

Concerning the first correction target side 109, the holes arranged within the second and the third quadrants are located in the backside of the correction target hole 101 and thus are out of the visual range, and therefore it is artificially considered that such holes are not affected by the proximity effect.

However, in reality, the influence of the proximity effect from the holes located in the second and the third quadrants is not zero, and such influence have no smaller effect on the dimensional change of the correction side by the proximity effect, and thus the correction is obliged to be.

However, smaller influence of the proximity effect is made on the holes disposed in the second and the third quadrants, as compared with the influence on the holes disposed in the first and the fourth quadrants. Thus, if the correction is performed without a correction factor, the correction is made with the same correction-weighting as for the holes disposed in the first and the fourth quadrants, leading to an excessive correction. Thus, the correction-weighting is reduced for the holes disposed in the second and the third quadrants, as compared with the holes disposed in the first and the fourth quadrants. More specifically, the adjustment of the correction can be achieved by multiplying by the correction factor of 0<a<1, thereby obtaining appropriate correction levels.

By following the above-mentioned OPC process flow, the bias correction values for four correction sides of the correction target hole 101 are defined. While the method for correcting the first correction target side 109 and the second correction target side 111 is exemplified in the above description, the bias correction levels for the other two sides of the correction target hole 101 may also be defined, according to the first correction target side 109 and the second correction target side 111.

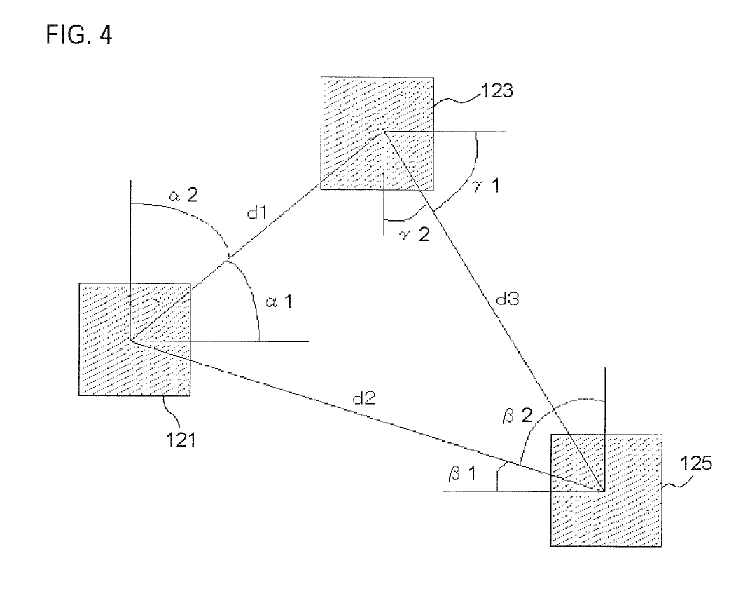

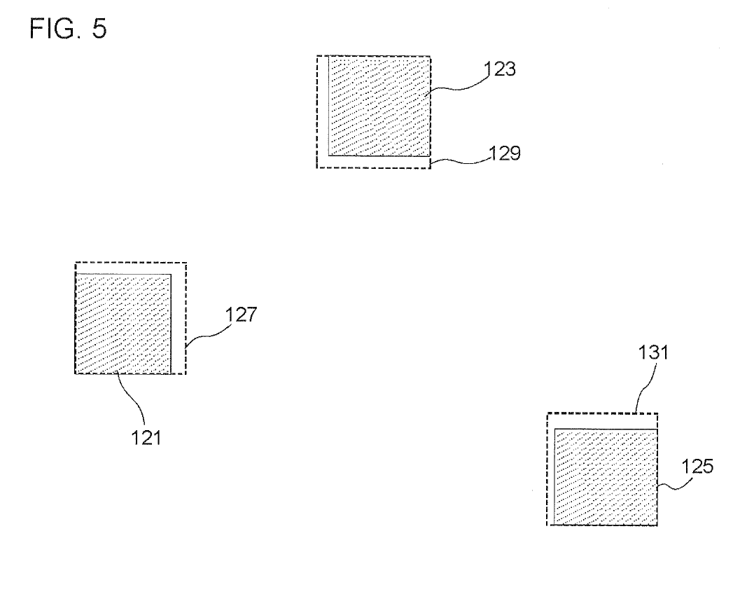

An example of the correction of the transfer pattern (mask) having three holes disposed therein will be described as follows, in reference to FIG. 4 and FIG. 5. FIG. 4 is a plan view, showing holes as mask data before the OPC correction. FIG. 5 is a plan view, showing holes after performing the OPC correction for four sides of each hole.

As shown in FIG. 4, three holes, namely a first hole 121, a second hole 123 and a third hole 125 are positioned in relation to spaces (d1, d2, d3) and angles (for example, α1, α2, β1, β2, γ1, γ2), for respective adjacent holes, and the correction levels are determined by the correlation there between. d1 is a center-to-center distance between the first hole 121 and the second hole 123, d2 is a center-to-center distance between the first hole 121 and the third hole 125, and d3 is a center-to-center distance between the second hole 123 and the third hole 125.

The OPC-corrected holes corrected by the correction levels determined by the above-described formula (I) on the basis of the spaces and the angles for the adjacent holes are shown in FIG. 5. A first hole corrected pattern 127 obtained by correcting the first hole 121, a second hole corrected pattern 129 obtained by correcting the second hole 123, and a third hole corrected pattern 131 obtained by correcting the third hole 125 are presented by dotted lines, respectively, in FIG. 5. As shown in FIG. 5, the correction level (subtracting level) is increased for the side related to larger number of adjacent holes.

According to the method for designing a mask of the present embodiment, sufficient correction can be achieved even for the pattern located out of the visual range from the correction target side, in additional consideration of influences of the locations out of the visual range from the correction target side, by suitably defining the bias correction value (to be smaller than in the front location) so that the correction accuracy can be beneficially improved as compared with the method for designing a mask according to the conventional technology.

Further, in the present embodiment, the bias correction level can be adjusted according to the locations of the hole for the correction target hole 101 by adding the function of angle when the bias correction level is determined, even if a number of adjacent holes are present, such that the bias correction level is reduced as compared with the conventional technology, thereby providing an improved correction accuracy.

Even if the angle is added to the correction factor, the processing time can be reduced as compared with a model OPC, since the method for the correction with a rule base OPC is employed. Here, a difference in processing time due to a difference in the correction process flows between the model-base OPC and the rule base OPC will be described.

The method for correcting by the model-base OPC is performed through the following flow.

(i) exposing and processing pattern;

(ii) measuring length of the pattern;

(iii) inputting the requirements of exposure and measured length into a model fitting parameter;

(iv) carrying out the model fitting;

(v) the fitting result is examined, and a parameter is changed;

(vi) performing a model fitting once again; and

(vii) the above (iv) to (vi) are repeated until the fitting remaining error is satisfied with the criteria.

A simulation fitting parameter is determined by the operations until the above described flow.

### Next,

(viii) for all contact geometries, simulations are performed by employing the fitting parameter obtained in the above-described operation, such that the correction level is calculated by performing such correction process. The correction processes with the simulations are repeated predetermined cycles by employing the fitting parameter for (all) corrected geometries to determine the final correction geometry and the optimum correction level. In the model-base OPC, greater processing time is required for repeating the correction process through the (viii) simulation.

On the contrary, in the rule base OPC, once the bias table is defined, and then it is sufficient to conduct only step 22 for calculating the correction level, so that the processing time can be reduced by about 1/10.

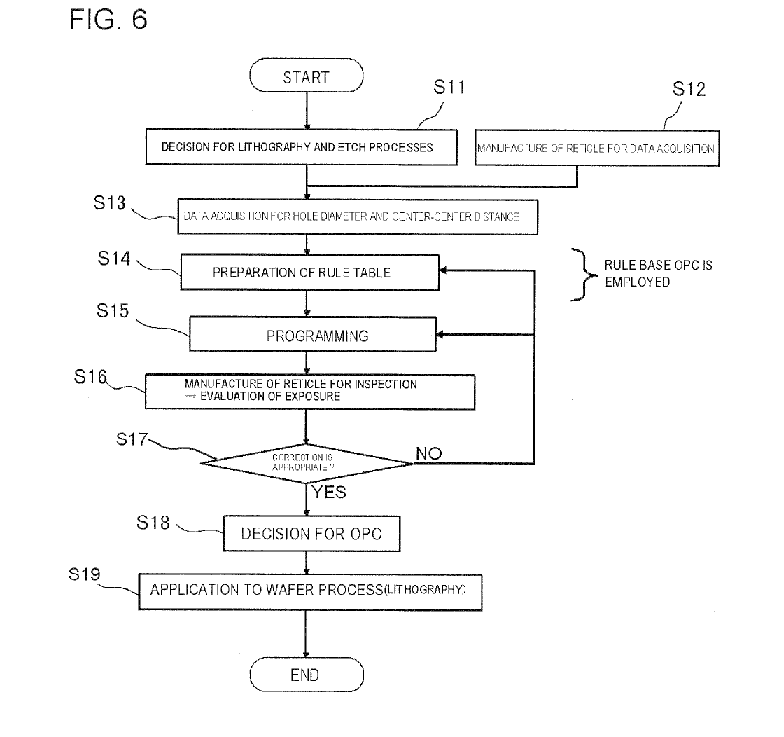

FIG. 6 is flow chart, showing a serial correction flow including the above-described steps of the rule base OPC. In addition to above, this flow can also be applied to any of the embodiments of the present invention. Flow of FIG. 6 includes the following procedures.

step 11: decision for lithography and etch processes;

step 12: manufacture of a reticle for data acquisition (including the above-described (i) pattern exposure and processing);

step 13: acquisition of data for hole diameter and center-to-center distance (corresponding to (ii) length measurement);

step 14: preparation of the rule table (corresponding to the above-described (iii) to (viii));

step 15: programming

step 16: manufacture of a reticle for inspection, and evaluation of the exposure;

step 18: decision for OPC; and

step 19: application of wafer process (lithography).

Here, the rule base OPC according to the bias correction described above corresponds to a section of “PREPARATION OF RULE TABLE” (step 14) in the flow of FIG. 6.

In FIG. 6, once the processes of lithography and etch are decided (step 11), then a reticle employed for the data acquisition for the hole diameter and the center-to-center distance is prepared (step 12). Then, the operations are performed in a procedure, in which, according to the predetermined lithography and etch processes, a pattern processing is performed on a wafer by employing the reticle, and then an acquisition of data for hole diameter and center-to-center distance of the patterned wafer is performed (step 13) to prepare a bias rule table (step 14). In addition, in step 14, the prepared bias rule table and the correction reference holes 103 are extracted, and then the correction levels are determined on the basis of these conditions. The sections for determining the correction level as presented by (iii) to (viii) in the flow of the correction process of the model-base OPC corresponds to step 14. Since the operation of (viii) requires greater amount of time in the case of the model-base OPC, time required for such operation can be considerably reduced by employing the rule base OPC.

Then, a program for performing the correction is prepared based on the obtained rule table (step 15). Here, the program is one for reflecting the correction level determined in step 14 on the pattern on the reticle, and for determining a routine for performing the correction and a routine of a graphical processing. The reticle for inspection is manufactured by employing such program, and then the evaluation for the exposure is performed (step 16). If it is judged that the correction level is not appropriate in step 16 (NO of step 17), the procedure returns to step 14 or step 15. If it is judged that there is no particular problem in practical use in the pattern manufactured for inspection (YES of step 17), the OPC is determined (step 18), and then the determined correction method is applied in the real wafer process (step 19). The procedure from step 15 to step 19 is the flow commonly applicable to both of the rule base OPC and the model-base OPC.

### Third Embodiment

The present embodiment relates to a method for manufacturing the semiconductor device employing the method for designing the mask as described in the above-mentioned embodiments. In the present embodiment, the correction levels for the respective sides of the correction target hole is determined according to the first embodiment or the second embodiment, and then a mask (reticle) is manufactured on the basis of such correction level.

FIG. 7 is a cross-sectional view, showing a configuration of a semiconductor device of the present embodiment. In the semiconductor device shown in FIG. 7, an interlayer insulating film 203 and an interlayer insulating film 205 are stacked on a silicon substrate 201 in this sequence. One of the interlayer insulating film 203 and the interlayer insulating film 205 may be a multiple-layered film having a plurality of insulating films.

Transistors and isolation regions 209 are provided in predetermined locations of the silicon substrate 201. Such transistor includes gate insulating films 211 and gate electrodes 213, which are stacked on the silicon substrate 201, side surface insulating films 215 covering the side surfaces of the gate electrodes 213, and source-drain regions 207 provided in the silicon substrate 201 in the lateral sides of the gate electrode 213.

The interlayer insulating film 203 is provided with contact holes 217 on the source-drain region 207, and each of the contact holes 217 is provided with a contact plug 219 embedded therein.

The interlayer insulating film 205 includes interconnects 221 embedded therein, which is coupled to the contact plugs 219, and via plugs 225 and a metallic film 227 serving as a top interconnect are formed on the interconnect 221 in this order. The via plugs 225 for coupling the metallic film 227 with the via holes 223 are embedded in the via holes 223 provided in the interlayer insulating film 205.

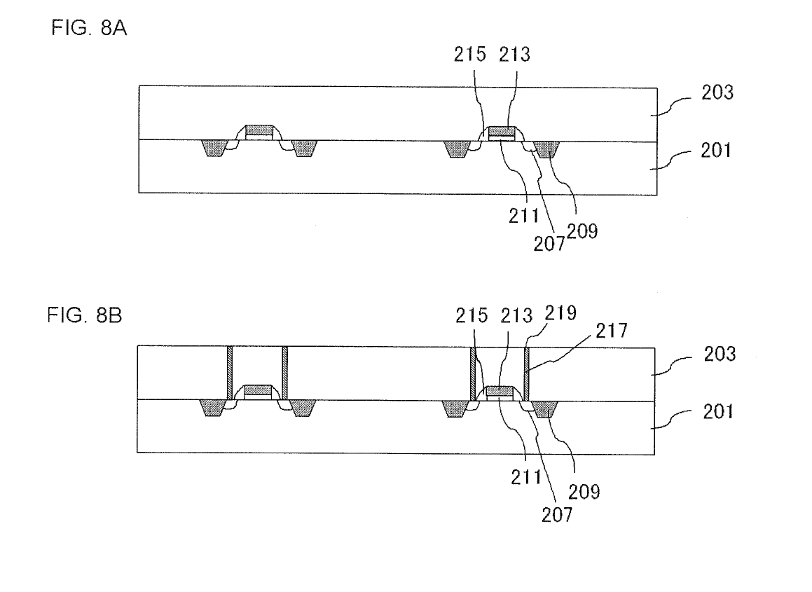

Next, a method for manufacturing the semiconductor device shown in FIG. 7 will be described. FIG. 8A and FIG. 8B are cross-sectional views, illustrating a process for manufacturing a semiconductor device shown in FIG. 7.

First of all, as shown in FIG. 8A, elements such as transistors are formed on the silicon substrate 201 to form the interlayer insulating film 203.

Then, on the interlayer insulating film 203 is applied with a film covering thereof (resist: not shown). Then, the predetermined locations in the resist are selectively removed by employing a mask prepared by the method of the first embodiment or the second embodiment to form the hole pattern in the resist. Portions of the interlayer insulating film 203 in locations corresponding to the hole pattern of the resist are selectively removed by an etching to form the contact holes 217, which extend through the interlayer insulating film 203 and provide a coupling with a transistor. The interior of the contact hole 217 is filled with a predetermined electrically conducting film, and subsequently a chemical mechanical polishing or the like is performed to form contact plugs 219 coupled to the source-drain region 207 in the interlayer insulating film 203 (FIG. 8B).

Further, the interconnects 221, the via plugs 225 and the metallic film 227, which are coupled to the top of the contact plug 219, are consecutively formed. Among these, the process operations for forming the via holes 223 having via plug 225 embedded therein also employs a patterned mask designed by employing the embodiment described above, similarly as in the formation of the contact hole 217. The semiconductor device shown in FIG. 7 is obtained by the above-mentioned procedure.

Since the patterned mask corrected according to the method in the embodiment described above is employed when the contact hole 217 is formed in the interlayer insulating film 203 in the present embodiment, the contact holes 217 can be formed in the locations as originally designed with certainty. Thus, an improved production yield of the semiconductor devices is provided. While the descriptions here feature mainly on the contact holes 217, the configuration may also be applicable to the via holes 223 for providing coupling between the interconnects.

While embodiments of the present invention have been fully described in reference to the annexed figures, it is intended to present these embodiments for the purpose of illustrations of the present invention only, and various modifications thereof are also available.

It is apparent that the present invention is not limited to the above embodiment, and may be modified and changed without departing from the scope and spirit of the invention.

What is claimed is:

1. A method for designing a mask having a hole pattern, comprising:
extracting a peripheral hole existing in a region, which is capable of affecting a formation of a correction target hole;
defining a bias correction level employed in the formation of said correction target hole, in accordance with a two-dimensional arrangement of said peripheral hole extracted in said extracting peripheral holes.
wherein, in said defining a bias correction level, said bias correction level is defined on the basis of center-to-center distance between said peripheral hole extracted in said extracting peripheral holes and said correction target hole, and on the basis of angle between line connecting center of said peripheral hole to center of said correction target hole and bias axis of said correction target hole.

2. The method for designing a mask as set forth in claim 1, wherein said defining a bias correction level includes:
acquiring a relationship between a distance from a center of said correction target hole to a center of said peripheral hole and said bias correction level;
calculating a center-to-center distance between said peripheral hole extracted in said extracting peripheral holes and said correction target hole; and
defining said bias correction level from said center-to-center distance calculated in said calculating a center-to-center distance, in reference to the relationship acquired in said acquiring a relationship between a distance from a center of said correction target hole and said bias correction level.

3. The method for designing a mask as set forth in claim 2,
wherein, in said calculating a center-to-center distance, a center-to-center distance for each of “n” peripheral holes (n is a positive integer) extracted in said extracting peripheral holes are calculated, and
wherein, in said defining a bias correction level, “n” bias correction levels corresponding to each of the “n” center-to-center distances obtained in said calculating a center-to-center distance is acquired in reference to said relationship, and said bias correction level is defined as a function a grand total of “n” bias correction levels.

4. The method for designing a mask as set forth in claim 1, wherein said defining a bias correction level includes:
defining a bias level of said correction target hole on the basis of said center-to-center distance;
defining a correction factor for said bias level as a function of said angle; and
utilizing a product obtained by multiplying said bias level by said correction factor as said bias correction level in a direction along said bias axis.

5. The method for designing a mask as set forth in claim 1, wherein said defining a bias correction level includes defining bias correction levels in a first bias axis-direction and in a second bias axis-direction, respectively, said first bias axis-direction being not in parallel with said second bias axis-direction.

6. The method for designing a mask as set forth in claim 2, wherein said defining a bias correction level includes defining bias correction levels in a first bias axis-direction and in a second bias axis-direction, respectively, said first bias axis-direction being not in parallel with said second bias axis-direction.

7. The method for designing a mask as set forth in claim 5, wherein said defining a bias correction level includes:
acquiring a relationship between a distance from a center of said correction target hole and the bias level;
calculating center-to-center distance between said peripheral hole extracted in said extracting peripheral holes and said correction target hole;
acquiring a first correction factor being a function of an angle between first line connecting a center of first correction reference hole to center of the correction target hole and the first bias axis on the first bias axis;
acquiring a second correction factor being a function of an angle between second line connecting center of second correction reference hole to center of the correction target hole and the second bias axis on the second bias axis;
defining a bias correction level in said first bias axis-direction for said first bias axis as a function of a product of said bias level multiplied by said first correction factor; and
defining a bias correction level in said second bias axis-direction for said second bias axis as a function of a product of said bias level multiplied by said second correction factor.

8. The method for designing a mask as set forth in claim 6, wherein said defining a bias correction level includes:
acquiring a relationship between a distance from a center of said correction target hole and the bias level;
calculating center-to-center distance between said peripheral hole extracted in said extracting peripheral holes and said correction target hole;
acquiring a first correction factor being a function of an angle between first line connecting a center of first correction reference hole to center of the correction target hole and the first bias axis on the first bias axis;
acquiring a second correction factor being a function of an angle between second line connecting center of second correction reference hole to center of the correction target hole and the second bias axis on the second bias axis;
defining a bias correction level in said first bias axis-direction for said first bias axis as a function of a product of said bias level multiplied by said first correction factor; and
defining a bias correction level in said second bias axis-direction for said second bias axis as a function of a product of said bias level multiplied by said second correction factor.

9. The method for designing a mask as set forth in claim 7, wherein, in said defining a bias correction level, a product of said bias level multiplied by said first correction factor is calculated for each of “n” peripheral holes (n is a positive integer) extracted in said extracting peripheral holes, and a bias correction level in said first bias axis-direction is determined by sum of said products, and a product of said bias level multiplied by said second correction factor is calculated for each of “n” peripheral holes extracted in said extracting peripheral holes, and a bias correction level in said second bias axis-direction is determined by sum of said products.

10. The method for designing a mask as set forth in claim 8, wherein, in said defining a bias correction level, a product of said bias level multiplied by said first correction factor is calculated for each of “n” peripheral holes (n is a positive integer) extracted in said extracting peripheral holes, and a bias correction level in said first bias axis-direction is determined by sum of said products, and a product of said bias level multiplied by said second correction factor is calculated for each of “n” peripheral holes extracted in said extracting peripheral holes, and a bias correction level in said second bias axis-direction is determined by sum of said products.

11. A method for manufacturing a semiconductor device, comprising:
preparing a mask by employing a method for designing a mask as set forth in claim 1;
forming an insulating film on or over a semiconductor substrate;
forming a film on or over said insulating film, said film covering said insulating film;
selectively removing a predetermined region of said film by employing said mask to form said hole pattern in said film; and
selectively removing a region corresponding to said hole pattern of said insulating film to form a hole extending through said insulating film.
